(19) United States
(12) Patent Application Publication
(10) Pub. No.: US 2025/0201570 A1
(43) Pub. Date: Jun. 19, 2025

(54) WAFER PROCESSING METHOD AND WAFER PROCESSING SYSTEM

(71) Applicant: HITACHI HIGH-TECH CORPORATION, Minato-ku, Tokyo (JP)

(72) Inventors: He WANG, Tokyo (JP); Koji FUJISAKI, Tokyo (JP); Kazumasa OKUMA, Tokyo (JP); Kenichi KUWAHARA, Tokyo (JP)

(21) Appl. No.: 18/845,667

(22) PCT Filed: Jun. 1, 2023
(86) PCT No.: PCT/JP2023/020475

§ 371 Date: Sep. 10, 2024

(51) Int. Cl. H01L 21/3065; H01L 21/67

(52) U.S. Cl. CPC H01L 21/3065; H01L 21/67069

(57) ABSTRACT

An object of the invention is to provide a technique capable of etching silicon with high accuracy by removing a natural oxide film. One wafer processing method according to the invention is a wafer processing method for providing a semiconductor wafer formed with a silicon film on an upper surface in a processing chamber and processing the silicon film. The wafer processing method includes: a step of forming a first modified layer by supplying particles of hydrogen, nitrogen, and fluorine gases to an oxide film formed on a surface of the silicon film; a first desorption step of heating and desorbing the first modified layer; a step of forming a second modified layer by supplying particles of a chlorine gas to the silicon film after the first desorption step; and a second desorption step of heating and desorbing the second modified layer.

### TECHNICAL FIELD

The present invention relates to a wafer processing method and a wafer processing system.

### BACKGROUND ART

In the field of semiconductor devices, with respect to a reduction in power consumption and an increase in storage capacity, higher integration due to further miniaturization, three-dimensional stacking of device structures, and the like has progressed. A device having a stacked three-dimensional structure has a three-dimensionally complicated structure as compared to a device having a related-art structure, and in manufacturing of the structure, isotropic etching capable of etching in a lateral direction with respect to a wafer surface is frequently used. On the other hand, with the progress of the miniaturization, there is also an increasing need for a lateral processing technique at an atomic layer level, and development of the technique is important.

Atomic layer etching (ALE) is known as the processing technique at an atomic layer level. PTL 1 discloses a method for etching a material on a substrate. The method disclosed in PTL 1 includes specifying a process condition for an atomic layer etching process for a material using a modification gas and a removal gas, and executing the atomic layer etching process on the material on the substrate as follows: the substrate is exposed to the modification gas to modify a surface of the material, and the modified surface is exposed to the removal gas and plasma is ignited to remove the modified surface, here the modification gas having modified energy and desorption energy for the material to be etched, the modified energy being smaller than the desorption energy, and the desorption energy being smaller than surface bonding energy of the material. In PTL 1, specifically, an atomic layer etching (ALE) technique for silicon is disclosed, and a cycle of generating the plasma using a chlorine gas, forming an altered SiClₓ layer on a silicon surface, then applying a wafer bias, and removing the SiClₓ layer with Ar ions is repeated. An ALE window having a self-limiting property in which an etching rate is changed by a bias voltage is searched for, and the atomic layer etching for silicon is attained.

On the other hand, a process of removing a natural oxide film before etching silicon is required. PTL 2 discloses a removal method for removing a silicon oxide film formed on a surface of a workpiece W, in which an HF gas and an NH₃ gas are used, and a removal step of removing the silicon oxide film is performed by setting a processing temperature within a range of 150° C. to 200° C.

### CITATION LIST

### Patent Literature

PTL 1: US2020/0118835A
PTL 2: JP2010-109335A

### SUMMARY OF INVENTION

### Technical Problem

In the ALE technique for silicon disclosed in PTL 1, the following three points are not sufficiently considered. The first point is that processing in a horizontal direction is difficult since the processing is performed in an ionic environment.

The second point is that roughness may occur due to ion sputtering.

The third point is that the ALE window having the self-limiting property is narrow.

In the technique of etching a silicon natural oxide film disclosed in PTL 2, the silicon natural oxide film is removed, but an etching processing process for silicon after the removal is not studied. Therefore, in the case of contiguous etching silicon, it is necessary to transfer a semiconductor wafer to another device, and there is a problem in efficiency of manufacturing a semiconductor device.

That is, in the above technique in the related art, in a silicon etching step, problems that a silicon layer is etched isotropically by removing the natural oxide film on silicon and that an etching amount is controlled uniformly over an entire surface of the three-dimensional structure with high accuracy have not been considered.

The invention is obtained in consideration of the problems in the related art, and an object thereof is to provide a technique capable of etching silicon with high accuracy by removing a natural oxide film.

### Solution to Problem

In order to solve the above problems, a typical wafer processing method according to the invention is a wafer processing method for providing a semiconductor wafer formed with a silicon film on an upper surface in a processing chamber and processing the silicon film, and the wafer processing method includes: a step of forming a first modified layer by supplying particles of hydrogen, nitrogen, and fluorine gases to an oxide film formed on a surface of the silicon film; a first desorption step of heating and desorbing the first modified layer; a step of forming a second modified layer by supplying particles of a chlorine gas to the silicon film after the first desorption step; and a second desorption step of heating and desorbing the second modified layer.

### Advantageous Effects of Invention

According to the invention, the etching for silicon can be performed with high accuracy by removing a natural oxide film.

Problems, configurations, and effects other than those described above will become apparent by description of the following embodiment.

### BRIEF DESCRIPTION OF DRAWINGS

FIG. 1 illustrates schematic diagrams of an etching step in a semiconductor device manufacturing process.

FIG. 2 is a schematic diagram of an etching processing apparatus.

FIG. 3A illustrates process schematic diagrams of an etching processing method according to the present embodiment.

FIG. 3B illustrates process schematic diagrams of the etching processing method according to the present embodiment.

FIG. 4 is a diagram illustrating an experiment result of a dependency relationship between an etching amount and a cycle in the etching processing method according to the present embodiment.

FIG. 5A is a diagram illustrating a test result related to dependency between an etching amount of polysilicon based on the etching processing according to the present embodiment and an irradiation time of fluorine radicals, nitrogen radicals, and hydrogen radicals in a step (a) in FIG. 3B.

FIG. 5B is a diagram illustrating a test result related to dependency between the etching amount of polysilicon based on the etching processing according to the present embodiment and an adsorption time of chlorine radicals in a step (b) in FIG. 3B.

FIG. 6 is a diagram illustrating dependency between etching amounts of polysilicon and an oxide film and the number of cycles when the step (a) in FIG. 3B to a step (d) in FIG. 3B are repeated.

FIG. 7 is a schematic diagram illustrating a configuration of a wafer processing system for executing a wafer processing method according to the present embodiment.

### DESCRIPTION OF EMBODIMENTS

Hereinafter, an embodiment according to the invention will be described with reference to the drawings. The invention is not limited to the embodiment. In the description of the drawings, the same portions are denoted by the same reference signs.

In the disclosure, the term “natural oxide film” refers to an oxide film other than an intentionally formed oxide film. It is distinguished from an oxide film formed by thermal oxidation of Si, an oxide film formed by a chemical vapor deposition (CVD) method, an oxide film formed using oxygen radicals, and the like. When an oxide film is to be formed on a surface parallel to a main surface of a wafer, an oxide film that is not formed at an intended location, such as an oxide film formed on a surface perpendicular to the main surface of the wafer, is also referred to as the natural oxide film.

The term “window” refers to an appropriate process condition when a certain process is performed.

The term “upper” means a vertically upward direction when a plate-shaped member or a layer is horizontally placed. The term “lower” means a vertically downward direction when the plate-shaped member or the layer is horizontally placed. For example, when the plate-shaped member or the layer in the plate-shaped member is illustrated, a surface illustrated on an upper side or a lower side in the drawing may be referred to as an “upper surface” or a “lower surface”.

### (Example in Related Art)

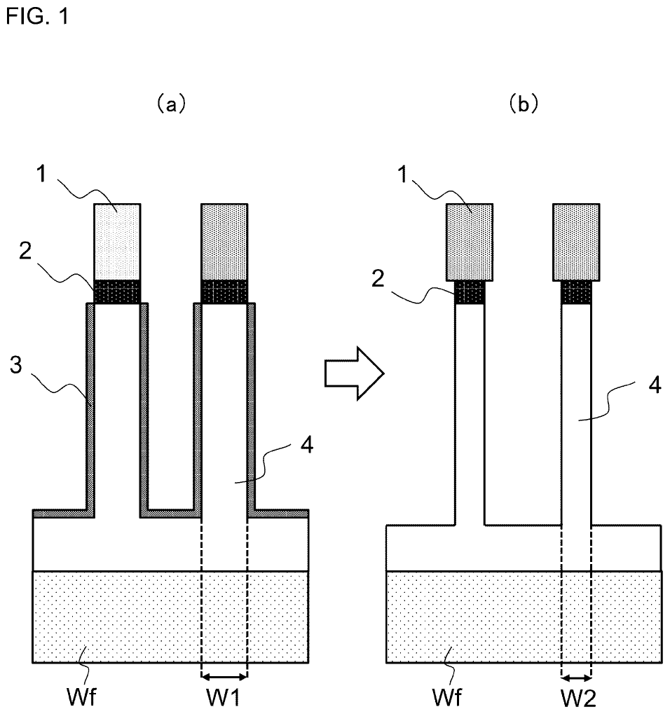

A silicon etching target film and a pattern processing example will be described with reference to FIG. 1. FIG. 1 illustrates schematic diagrams of an etching step in a semiconductor device manufacturing process. (a) of FIG. 1 is a diagram illustrating an example of a cross section as an etching processing target. (b) of FIG. 1 is a diagram illustrating a state after etching is performed on the processing target. As illustrated in (a) of FIG. 1, a silicon film 4 as a processing target is, for example, a silicon film formed on a wafer Wf. In the silicon film 4, an uneven shape is formed in a direction perpendicular to a main surface of the wafer Wf, and a so-called trench (groove) structure is formed. A width of a protruding portion of the trench (a length in a direction parallel to a direction of the main surface of the wafer Wf) is W1. A silicon nitride film 1 is a film formed of a compound of silicon and nitrogen. A silicon oxide film 2 is a film formed of a compound of silicon and oxygen. The silicon nitride film 1 and the silicon oxide film 2 have a predetermined pattern shape and function as masks (hard masks) in the etching step. A natural oxide film 3 is formed on a surface of the silicon film 4. The natural oxide film 3 is formed on the surface of the silicon film 4 under the influence of oxygen and moisture. The silicon oxide film 2 is an intentionally formed oxide film so as to function as a mask, but the natural oxide film 3 is an unintentionally formed oxide film.

(b) of FIG. 1 illustrates a case where ideal etching processing is performed. Since the etching is performed isotropically, the groove is enlarged in the direction parallel to the main surface of the wafer Wf. A width W2 of a protruding portion is smaller than the width W1 before the processing. The natural oxide film 3 is also removed by a formed amount, and the shape of the silicon film 4 is maintained as it is.

However, it is difficult to acquire the shape as illustrated in (b) of FIG. 1 in reality. When an etching process is performed without removing the natural oxide film 3, surface roughness of the silicon film 4 deteriorates, and electrical characteristics of the semiconductor device may be adversely influenced.

### (Configuration of Etching Processing Apparatus)

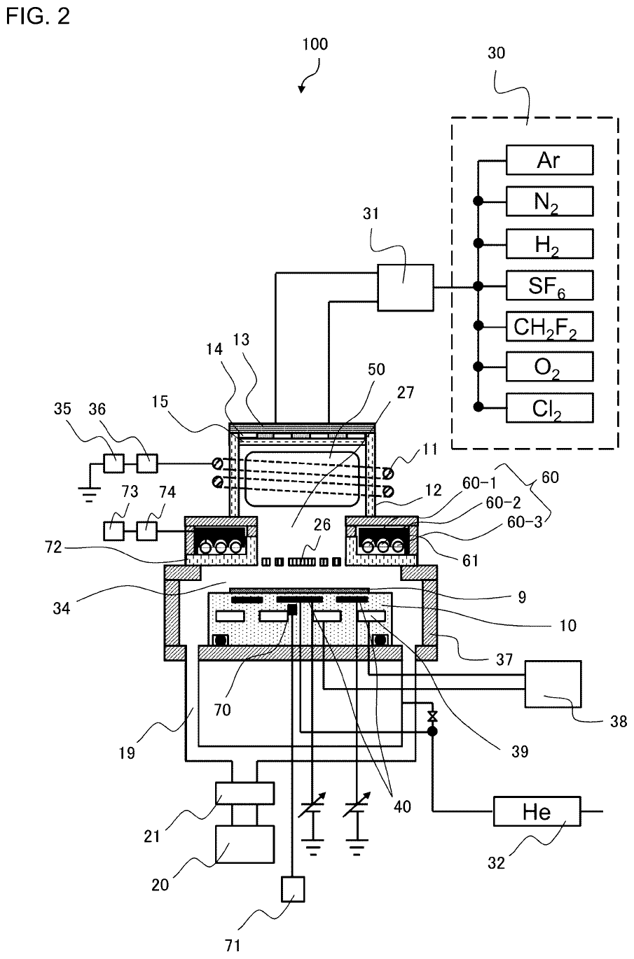

An overall configuration of an etching processing apparatus 100 will be schematically described with reference to FIG. 2. FIG. 2 is a schematic diagram of the etching processing apparatus 100. A processing chamber 34 includes a base chamber (vacuum container) 37, and a wafer stage 10 on which a wafer 9 is placed is provided in the base chamber 37. A plasma source (ICP plasma source) using an inductively coupled plasma (ICP) discharge method is provided above the processing chamber 34. The ICP plasma source is used to generate a reactive gas by plasma, and is used to clean an inner wall of the chamber or to process a film layer as a processing target on the wafer.

A cylindrical discharge tube 12 including the ICP plasma source is provided above the processing chamber 34, and an ICP coil 11 is provided outside the discharge tube 12. A radio-frequency power supply 35 is connected to the ICP coil 11 via a matching device 36 to supply radio-frequency power for plasma generation. As a frequency of the radio-frequency power, a frequency in a frequency band of several tens of MHz such as 13.56 MHz is applied. A top plate 13 is provided on an upper portion of the discharge tube 12. A gas dispersion plate 14 and a shower plate 15 are provided below the top plate 13, and a processing gas is introduced into the discharge tube 12 via the gas dispersion plate 14 and the shower plate 15.

A supply flow rate of the processing gas is adjusted by a mass flow controller 30 provided for each gas type. A gas distributor 31 is provided downstream of the mass flow controller 30, and supplies a gas supplied to the vicinity of a center of the discharge tube 12 and a gas supplied to the vicinity of an outer periphery of the discharge tube 12 while independently controlling a flow rate and a combination thereof. Accordingly, a spatial distribution of a partial pressure of the processing gas can be finely controlled. In FIG. 2, an example is illustrated in which an argon (Ar) gas, a nitrogen (N₂) gas, a hydrogen (H₂) gas, a sulfur hexafluoride (SF₆) gas, a difluoromethane (CH₂F₂) gas, an oxygen (O₂) gas, and a chlorine (Cl₂) gas are used as the processing gas, but other gases may be used.

An exhaust mechanism 20 is connected to a lower portion of the processing chamber 34 via a vacuum exhaust pipe 19 in order to depressurize the processing chamber 34. The exhaust mechanism 20 is implemented by, for example, a turbo molecular pump, a mechanical booster pump, or a dry pump, but the configuration is not limited thereto. In addition, in order to adjust the pressure of the processing chamber 34, a pressure-regulating mechanism 21 is provided in the vacuum exhaust pipe 19.

An IR lamp unit for heating the wafer 9 is provided above the wafer stage 10. The IR lamp unit includes an IR lamp 60, a reflection plate 61 that reflects IR light, and an IR light transmission window 72. Here, each of circular IR lamps 60-1, 60-2, and 60-3 is used as the IR lamp 60.

The IR lamp 60 emits light mainly including light in a range from visible light to infrared light (here, referred to as IR light). In this example, the IR lamps 60-1, 60-2, and 60-3 are concentrically arranged in three circles, but may be arranged in two or four or more circles. The reflection plate 61 that reflects the IR light downward (wafer installation direction) is provided above the IR lamp 60.

An IR lamp power supply 73 is connected to the IR lamp 60, and a high-frequency cut filter 74 that prevents noise of the high-frequency power from flowing into the IR lamp power supply 73 is provided between the IR lamp power supply 73 and the IR lamp 60.

The IR lamp power supply 73 is provided with a function of independently controlling the power supplied to the IR lamps 60-1, 60-2, and 60-3, and a radial distribution of a heating amount of the wafer can be adjusted (a part of wiring is not illustrated).

A flow channel 27 is formed at a center of the IR lamp unit. In the flow channel 27, an ion shielding plate 26 having a plurality of holes for preventing ions or electrons generated in the plasma and allowing a neutral gas or neutral radicals to pass therethrough to irradiate the wafer is provided.

A flow channel 39 of a coolant for cooling the wafer stage 10 is formed in the wafer stage 10, and a chiller 38 circulates and supplies the coolant through the flow channel 39. In order to fix the wafer 9 by electrostatic adsorption, a plate-shaped electrode plate 40 is embedded in the wafer stage 10 and is connected to a DC power supply.

In order to efficiently cool the wafer 9, a helium (He) gas whose flow rate is adjusted by a mass flow controller 32 can be supplied between a back surface of the wafer 9 and the wafer stage 10. In order to prevent the back surface of the wafer 9 from being damaged when the wafer 9 is heated or cooled while being adsorbed, a surface of the wafer stage 10 (wafer placement surface) is coated with a resin such as polyimide. Further, a thermocouple 70 for measuring a temperature of the wafer stage 10 is provided inside the wafer stage 10, and the thermocouple 70 is connected to a thermocouple thermometer 71.

### (Etching Process)

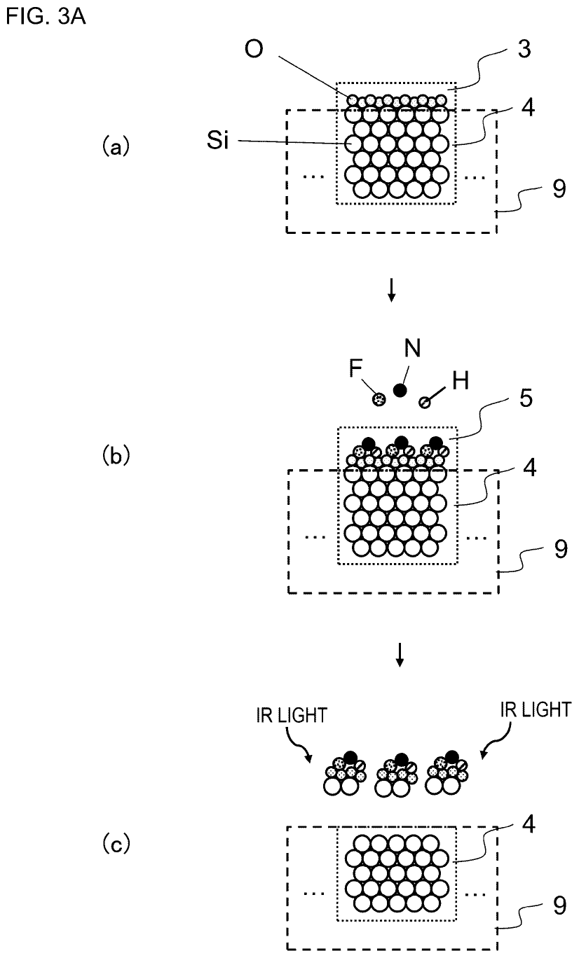

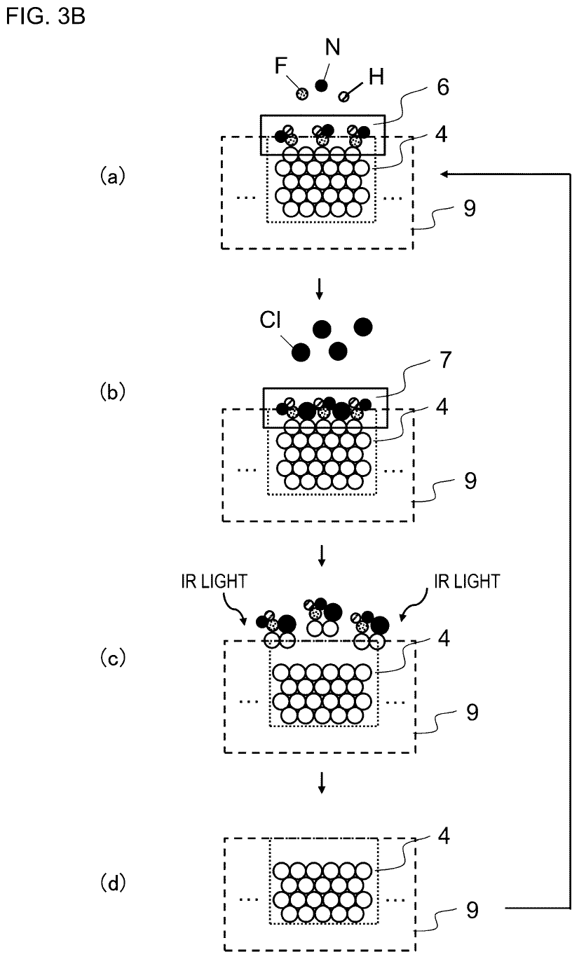

A wafer processing method according to the present embodiment will be described with reference to FIGS. 3A and 3B. In the wafer processing method, a semiconductor wafer formed with a silicon film (the silicon film 4) as a processing target on an upper surface is provided in a processing chamber, and the silicon film is processed. FIGS. 3A and 3B are process schematic diagrams illustrating an etching processing method according to the present embodiment. In FIGS. 3A and 3B, a part of a cross-sectional structure having a configuration of a processing target is illustrated, and is schematically represented using atoms that form the processing target. A natural oxide film is removed in a step illustrated in FIG. 3A, and an etching process on a film as a processing target is performed in a step illustrated in FIG. 3B. The processing illustrated in FIGS. 3A and 3B is performed in a state where the wafer 9 is placed on the wafer stage 10.

In a step (a) in FIG. 3A, an initial state of the silicon film 4 serving as a silicon film as a processing target is illustrated. The natural oxide film 3 is a natural oxide film formed in advance on the surface of the silicon film 4. The silicon film 4 is a silicon layer underlying the natural oxide film 3. The silicon film 4 contains regularly arranged silicon atoms. The natural oxide film 3 contains silicon atoms on the surface of the silicon film 4 and oxygen atoms adhering in a manner of covering the silicon atoms on the surface. In the disclosure, the etching processing is uniformly performed on two film types including the natural oxide film 3 and the silicon film 4 by the same apparatus. Detailed process steps will be described below.

The silicon film 4 is not limited to being formed on the upper surface of the wafer 9, and may be a silicon film formed on the wafer 9. When the wafer 9 is a silicon wafer, the silicon film 4 may be a surface of the wafer 9.

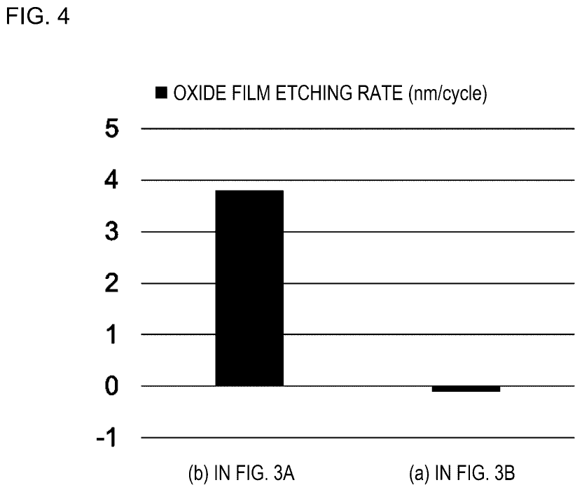

FIGS. 3A and 3B illustrate a state where the silicon film 4 is formed on the upper surface of the wafer 9 and a gas is supplied from the upper surface of the silicon film 4, but as illustrated in FIG. 4, for example, the silicon film 4 may be a film formed on a side surface of the groove structure. That is, the disclosure is applied not only to the natural oxide film 3 formed in a direction parallel to a main surface of the wafer 9 but also to the natural oxide film 3 formed in a direction perpendicular to the main surface of the wafer 9.

It is assumed that the natural oxide film 3 according to the disclosure is formed under a condition of being placed in the processing chamber 34 in a semiconductor manufacturing step. Since it is known that a thickness of about 1 nanometer (nm) corresponds to a thickness of one atomic layer, a one-layer film is represented in FIG. 3A.

A step (b) in FIG. 3A illustrates a step of forming a first modified layer by supplying particles of hydrogen, nitrogen, and fluorine gases to an oxide film formed in advance on a surface of a silicon film. The first modified layer contains ammonium fluorosilicate. In the step (b) in FIG. 3A, first, a sulfur hexafluoride gas, a nitrogen gas, and a hydrogen gas are supplied and introduced into a discharge region 50. Subsequently, the high-frequency power is supplied by turning on the high-frequency power supply 35, and plasma is formed in the discharge region 50. Fluorine (F) radicals, nitrogen (N) radicals, and hydrogen (H) radicals generated in the plasma are supplied to the processing chamber 34 via the flow channel 27 and the ion shielding plate 26, and are adsorbed on the surface of the wafer 9. The natural oxide film 3 is modified by reactions of the fluorine radicals, the nitrogen radicals, and the hydrogen radicals with the natural oxide film 3, and an ammonium fluorosilicate (NH₄)₂SiF₆ layer (first modified layer) 5 which is a compound containing silicon, nitrogen, fluorine, and hydrogen is formed on the surface of the silicon film 4.

A step (c) in FIG. 3A illustrates a first desorption step of heating and desorbing the first modified layer 5. In the first desorption step, the heating is performed by irradiating the inside of the processing chamber 34 with electromagnetic waves. Specifically, in the step (c) in FIG. 3A, argon (Ar) as an inert gas is supplied, the high-frequency power supply 35 is turned on to form the plasma in the discharge region 50, and the wafer 9 is heated by emitting an infrared ray (IR) by the IR lamp 60. According to this method, the natural oxide film 3 is etched (removed) by thermally decomposing and desorbing the first modified layer 5 formed on the surface of the silicon film 4. A temperature of the wafer 9 in this reaction is preferably 150° C. or higher. In other words, the silicon film 4 is heated to 150° C. or higher. Thereafter, the wafer 9 is cooled by turning off the IR lamp and supplying a helium (He) gas for wafer cooling to the back surface of the wafer 9, and the temperature of the wafer 9 is returned to the temperature of the wafer stage 10. This is to avoid diffusion of the silicon atoms from the surface of the silicon film 4.

A purge step of exhausting the inside of the processing chamber 34 to reduce the pressure may be included between the step (b) in FIG. 3A and the step (c) in FIG. 3A. The purge step is performed by operating the exhaust mechanism 20.

After the natural oxide film removal process from the step (a) in FIG. 3A to the step (c) in FIG. 3A is performed, the etching process on the silicon film 4 from a step (a) in FIG. 3B to a step (d) in FIG. 3B is performed.

The step (a) in FIG. 3B is a step after the step (c) (first desorption step) in FIG. 3A. In the step (a) in FIG. 3B, a layer (damaged layer 6) to which the particles of hydrogen, nitrogen, or fluorine adhere is formed on the surface of the silicon film 4. Specifically, in the step (a) in FIG. 3B, first, a sulfur hexafluoride gas, a nitrogen gas, and a hydrogen gas serving as the same gas system as that in the step (b) in FIG. 3A are supplied and introduced into the discharge region 50. Subsequently, the high-frequency power is supplied by turning on the high-frequency power supply 35, and plasma is formed in the discharge region 50. Fluorine radicals, nitrogen radicals, and hydrogen radicals generated in the plasma are supplied to the processing chamber 34 via the flow channel 27 and the ion shielding plate 26, and are adsorbed on the surface of the wafer 9. The fluorine radicals, the nitrogen radicals, and the hydrogen radicals react with the silicon film 4 to form the damaged layer 6. Thereafter, the gas containing fluorine, nitrogen, and hydrogen atoms and remaining in a gas phase is evacuated (purged).

Although the same gas system is used in the step (a) in FIG. 3B and the step (b) in FIG. 3A, by adjusting flow rate ratios of the sulfur hexafluoride gas, the nitrogen gas, and the hydrogen gas, it is also possible to increase a selectivity ratio to the natural oxide film which may be generated during the etching for the silicon layer in the process of the steps (a) to (d) in FIG. 3B. In FIG. 4, etching amounts of the oxide film before and after adjusting the flow rate ratios of the sulfur hexafluoride gas, the nitrogen gas, and the hydrogen gas in the step (a) in FIG. 3B and the step (b) in FIG. 3A is illustrated as an example. FIG. 4 is a diagram illustrating an experiment result of a dependency relationship between an etching amount and a cycle in the etching processing method according to the present embodiment. By adjusting the flow rate ratios, as illustrated in a graph denoted by (a) in FIG. 3B in FIG. 4, it is possible to substantially prevent the generation of the natural oxide film.

The step (b) in FIG. 3B is a step after the first desorption step. The step (b) in FIG. 3B illustrates a step of forming a second modified layer by supplying particles of a chlorine gas to the silicon film. Specifically, in the step (b) in FIG. 3B, first, a gas containing chlorine atoms (a chlorine (Cl₂) gas, a boron trichloride (BCl₃) gas, or the like) is introduced into the discharge region 50. The high-frequency power is supplied by turning on the high-frequency power supply 35, and the plasma is formed in the discharge region 50. Chlorine (Cl) radicals generated in the plasma are supplied to the processing chamber 34 via the flow channel 27 and the ion shielding plate 26, and are adsorbed on the surface of the wafer 9. The chlorine radicals react with the damaged layer 6 to form a layer (second modified layer) 7 which is a compound containing silicon, fluorine, hydrogen, nitrogen, and chlorine. Thereafter, the high-frequency power supply 35 is turned off to stop the plasma generation. Thereafter, the gas containing the chlorine atoms and remaining in a gas phase is evacuated.

The step (c) in FIG. 3B illustrates a second desorption step of heating and desorbing the second modified layer. In the second desorption step, the heating is performed by emitting electromagnetic waves. Specifically, in the step (c) in FIG. 3B, an argon (Ar) gas as an inert gas is supplied, the high-frequency power supply 35 is turned on to form the plasma in the discharge region 50, and the wafer 9 is heated by the IR lamp 60. According to this method, the second modified layer 7 is removed by thermally decomposing and desorbing the second modified layer 7 formed on the surface of the silicon film 4 as illustrated in the step (d) in FIG. 3B.

A purge step of exhausting the inside of the processing chamber 34 to reduce the pressure may be included between the step (b) in FIG. 3B and the step (c) in FIG. 3B. The purge step is performed by operating the exhaust mechanism 20.

### (Process Conditions)

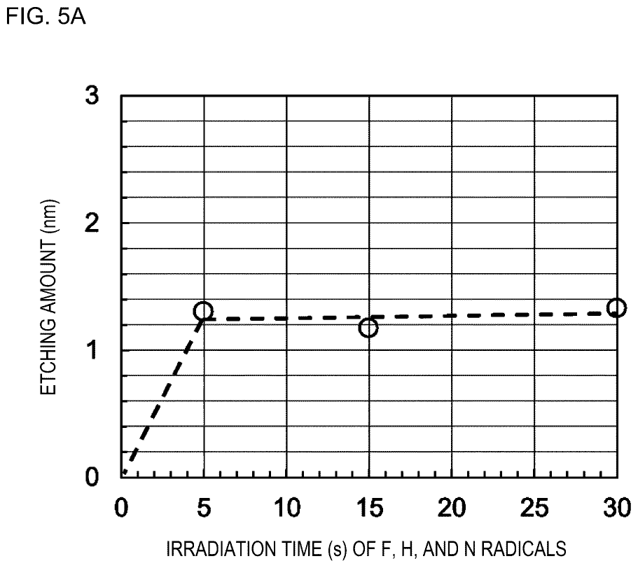

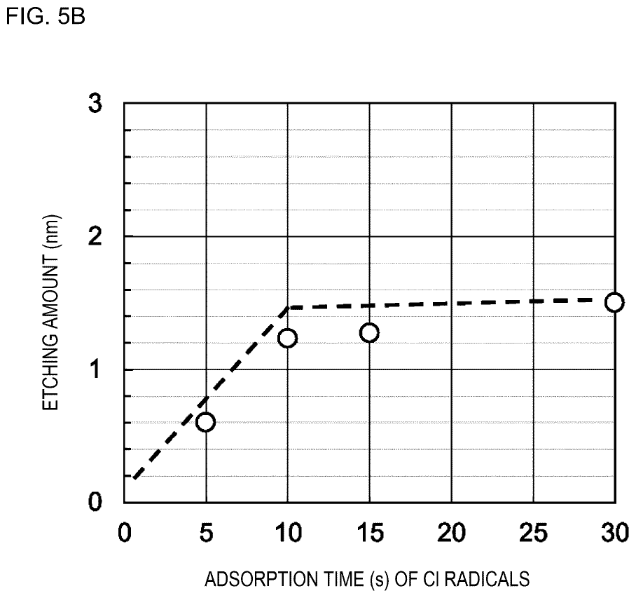

FIG. 5A is a diagram illustrating a test result related to dependency between an etching amount of polysilicon based on the etching processing according to the present embodiment and an irradiation time of the fluorine radicals, the nitrogen radicals, and the hydrogen radicals in the step (a) in FIG. 3B. FIG. 5B is a diagram illustrating a test result related to dependency between the etching amount of polysilicon based on the etching processing according to the present embodiment and an adsorption time of the chlorine radicals in the step (b) in FIG. 3B.

As illustrated in FIG. 5A, the etching amount of etching during a period from the formation of the second modified layer 7 (the step (a) in FIG. 3B) to the desorption of the second modified layer 7 (the step (d) in FIG. 3B) is saturated to about 1.2 nm when the irradiation time of radicals in the step (a) in FIG. 3B ranges from 5 (s) to 30 (s). As illustrated in FIG. 5B, the etching amount of etching during the period from the formation of the second modified layer 7 (the step (a) in FIG. 3B) to the desorption of the second modified layer 7 (the step (d) in FIG. 3B) is saturated to about 1.5 nm when the adsorption time, which is a time for adsorbing the chlorine radicals to the damaged layer 6 in the step (b) in FIG. 3B, ranges from 10 (s) to 30 (s).

Therefore, when the irradiation time in (a) in FIG. 3B is set in the range of 5 (s) to 30 (s) and the adsorption time in (b) in FIG. 3B is set in the range of 10 (s) to 30 (s), uniform etching capable of removing one atomic layer can be performed.

When the etching processing is to be performed on a pattern having a complicated structure such as a deep groove structure, it is necessary to increase the irradiation time and the adsorption time of radicals such that the radicals can reach a portion of the film as a processing target. On the other hand, when the irradiation time and the adsorption time of the radicals are excessively increased, deposition occurs on the contrary, and the surface roughness may deteriorate. Therefore, it is desirable to adjust the irradiation time and the adsorption time of the radicals according to a structure of a target pattern.

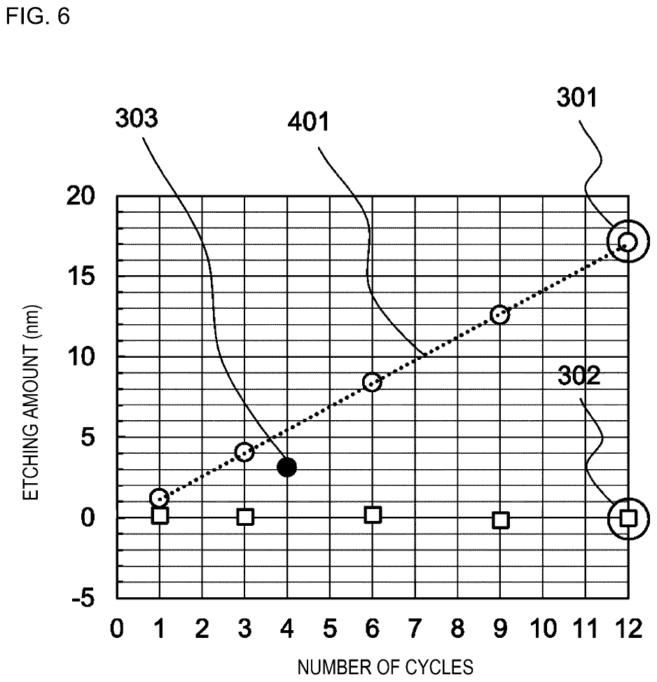

Here, according to the wafer processing method of the disclosure, a plurality of steps including the step of forming the second modified layer and the second desorption step are set as one cycle, and the cycle is performed a plurality of times to process the silicon film. Specifically, the surface of the silicon film 4 is exposed through the processes from the step (a) in FIG. 3B to the step (d) in FIG. 3B. When a desired etching amount is not satisfied, the process returns to the step (a) in FIG. 3B, and the etching amount can finally reach a desired value by repeating the step (a) in FIG. 3B to the step (d) in FIG. 3B. FIG. 6 is a diagram illustrating dependency between etching amounts of polysilicon and the oxide film and the number of cycles when the step (a) in FIG. 3B to the step (d) in FIG. 3B are repeated. A circle mark indicated by a point 301 indicates a test result of the etching amount of polysilicon, and a square mark indicated by a point 302 indicates a test result of the etching amount of the oxide film. A broken line 401 indicates a result of performing linear regression on the test result of the etching amount in the case of polysilicon. The test result is formed such that the broken line 401 passes through circle marks indicating measurement results. In this manner, as indicated by the broken line 401, the polysilicon can be etched linearly as the number of cycles increases. Since the etching amount of the oxide film does not increase even when the number of cycles increases, the polysilicon can be selectively etched.

In the invention, an embodiment is described using a polysilicon sample as an example of the silicon layer, but the same effect can be attained using a monocrystalline silicon layer or an amorphous silicon layer. FIG. 6 illustrates a comparison between the etching amount of the silicon layer and the etching amount of the polysilicon sample according to the invention. A point 303 is an etching amount of a monocrystalline silicon layer processed under the same conditions.

### (Wafer Processing System)

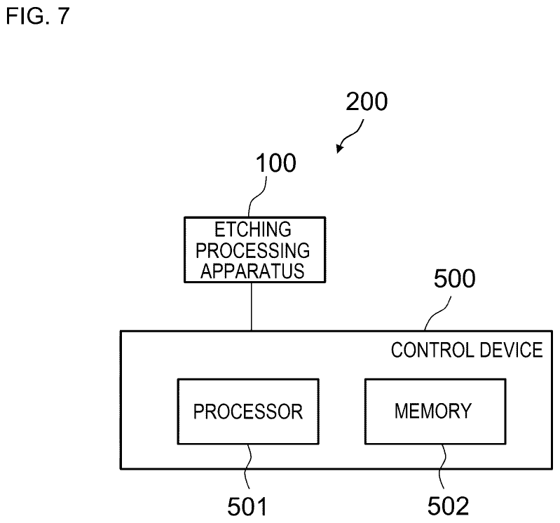

FIG. 7 is a schematic diagram illustrating a configuration of a wafer processing system 200 for executing the wafer processing method according to the present embodiment. The wafer processing system 200 includes the etching processing apparatus 100 and a control device 500. The control device 500 includes at least one processor 501 and at least one memory 502.

The control device 500 acquires a temperature from the thermocouple thermometer 71. The control device 500 controls operations of the exhaust mechanism 20, the pressure-regulating mechanism 21, the high-frequency power supply 35, the mass flow controllers 30 and 32, the chiller 38, and the IR lamp power supply 73. In addition, the control device 500 is connected to a sensor (not illustrated) in order to control operations of the etching processing apparatus 100, and controls a power supply or the like.

The memory 502 has a program. The program is configured to cause, when executed by the processor 501, the etching processing apparatus 100 to execute the wafer processing method described in the present embodiment.

### (Functions and Effects)

As indicated by the broken line 401 in FIG. 6, according to the wafer processing method of the disclosure, it is possible to perform linear etching as the number of cycles increases. Therefore, self-limiting atomic layer etching for the silicon film can be achieved.

According to the wafer processing method of the disclosure, the etching processing for the silicon film is performed in a radical environment as illustrated in, particularly, the step (a) and the step (b) in FIG. 3B. Since processing in an ionic environment can be avoided, there is an effect that processing in a direction parallel to the main surface of the wafer can be easily performed in addition to processing in a direction perpendicular to the main surface of the wafer.

The irradiation time and the adsorption time of radicals, which are conditions for causing a uniform etching amount, can be provided enough, and a process window can be secured. Since the irradiation time and the adsorption time are parameters that are relatively easy to control, it is easy to cope with the deterioration of the surface roughness.

According to the wafer processing method of the disclosure, since the processing gas is common, the removal of the natural oxide film and the atomic layer etching for the silicon film can be performed in the same etching processing apparatus. It is not necessary to transfer the wafer, and it is possible to avoid damaging efficiency of manufacturing a semiconductor device.

In this manner, according to the invention, the etching for silicon can be performed with high accuracy by removing the natural oxide film.

In the present embodiment, an example is illustrated in which the IR lamp 60 is used to heat the wafer, but the heating method is not limited thereto.

The invention is not limited to the embodiment described above and includes various modifications. For example, the embodiment described above has been described in detail in order to facilitate understanding of the invention, and is not necessarily limited to those including all the configurations described above. A part of a configuration according to a certain embodiment can be replaced with a configuration according to another embodiment, and a configuration according to another embodiment can also be added to a configuration according to a certain embodiment. A part of a configuration according to each embodiment can also be added to, deleted from, or replaced with another configuration.

Aspects that may be contents of the invention will be described below, but the invention is not limited thereto.

### (Aspect 1)

An etching processing method which is a processing method of etching a natural oxide film formed on silicon and a silicon layer, the etching processing method including:
placing the wafer on a wafer stage in a processing chamber in a vacuum container;
a step of forming a modified layer on the natural oxide film by supplying radicals of fluorine, nitrogen, and hydrogen to the wafer;
a step of heating the wafer to desorb and remove the modified layer formed on the natural oxide film;
a step of forming a modified layer on a silicon surface after the removal of the natural oxide film by supplying radicals of fluorine, nitrogen, and hydrogen to the wafer;
a step of supplying chlorine radicals to the wafer, further modifying the modified layer formed on the silicon surface, and performing heating and inert gas plasma discharge to desorb and remove the modified layer formed by adsorption of the chlorine radicals; and
repeating the step of forming the modified layer on the silicon and the step of desorbing and removing the formed modified layer.

### (Aspect 2)

The etching processing method according to Aspect 1, in which
in the step of forming the modified layer on the natural oxide film by supplying the radicals of fluorine, nitrogen, and hydrogen to the wafer and the step of forming the modified layer on the silicon surface after the removal of the natural oxide film by supplying the radicals of fluorine, nitrogen, and hydrogen to the wafer,
the same gas system containing the radicals of fluorine, nitrogen, and hydrogen is used, and a selectivity ratio to another film is maintained by adjusting a flow rate ratio of a gas.

### (Aspect 3)

An etching processing apparatus according to Aspect 1, in which
the modified layer formed on the silicon surface is a layer of a compound containing silicon, fluorine, nitrogen, hydrogen, and chlorine.

### (Aspect 4)

The consistent processing method according to Aspect 1, in which
silicon oxide film etching including natural oxide film etching and silicon etching are performed in the same apparatus.

### REFERENCE SIGNS LIST

1: silicon nitride film
2: silicon oxide film
3: natural oxide film
4: silicon film
5: first modified layer
6: damaged layer
7: second modified layer
9: wafer
10: wafer stage
11: ICP coil
12: discharge tube
13: top plate
14: gas dispersion plate
15: shower plate
19: vacuum exhaust pipe
20: exhaust mechanism
21: pressure-regulating mechanism
26: ion shielding plate
27: flow channel
30, 32: mass flow controller
34: processing chamber
35: high-frequency power supply
36: matching device
37: base chamber
38: chiller
39: flow channel
40: electrode plate
50: discharge region
60: IR lamp
61: reflection plate
70: thermocouple
71: thermocouple thermometer
72: IR light transmission window
73: IR lamp power supply
74: high-frequency cut filter
100: etching processing apparatus
200: wafer processing system
500: control device
501: processor
502: memory

1. A wafer processing method for providing a semiconductor wafer formed with a silicon film on an upper surface in a processing chamber and processing the silicon film, the wafer processing method comprising:
a step of forming a first modified layer by supplying particles of hydrogen, nitrogen, and fluorine gases to an oxide film formed on a surface of the silicon film;
a first desorption step of heating and desorbing the first modified layer;
a step of forming a second modified layer by supplying particles of a chlorine gas to the silicon film after the first desorption step; and
a second desorption step of heating and desorbing the second modified layer.

2. The wafer processing method according to claim 1, wherein
a plurality of steps including the step of forming the second modified layer and the second desorption step are set as one cycle, and the cycle is performed a plurality of times to process the silicon film.

3. The wafer processing method according to claim 1, wherein
the heating is performed by irradiating an inside of the processing chamber with an electromagnetic wave in the first desorption step or the second desorption step.

4. The wafer processing method according to claim 1, wherein
the silicon film is heated to 150° C. or higher in the first desorption step.

5. The wafer processing method according to claim 1, wherein
the first modified layer contains ammonium fluorosilicate.

6. The wafer processing method according to claim 1, wherein
a layer to which the particles of hydrogen, nitrogen, or fluorine adhere is formed on the surface of the silicon film after the first desorption step.

7. The wafer processing method according to claim 1, further comprising:
a purge step of exhausting an inside of the processing chamber to reduce a pressure between the step of forming the first modified layer and the first desorption step or between the step of forming the second modified layer and the second desorption step.

8. A wafer processing method for providing a semiconductor wafer formed with a silicon film in a processing chamber and processing the silicon film, the wafer processing method comprising:
a step of forming a first modified layer by supplying particles of hydrogen, nitrogen, and fluorine gases to the silicon film;
a step of forming a second modified layer by supplying particles of a chlorine gas to the first modified layer; and
a second desorption step of heating and desorbing the second modified layer.

9. The wafer processing method according to claim 8, wherein
a plurality of steps including the step of forming the second modified layer and the second desorption step are set as one cycle, and the cycle is performed a plurality of times to process the silicon film.

10. The wafer processing method according to claim 8, further comprising:
a purge step of exhausting an inside of the processing chamber to reduce a pressure between the step of forming the first modified layer and the step of forming the second modified layer or between the step of forming the second modified layer and the desorption step.

11. A wafer processing system for providing a semiconductor wafer formed with a silicon film on an upper surface in a processing chamber and processing the silicon film, the wafer processing system comprising:
an etching processing apparatus;
a processor; and
a memory having a program, wherein
the program is configured to cause, when executed by the processor, the etching processing apparatus to execute the wafer processing method according to claim 1.

12. The wafer processing method according to claim 2, wherein
the heating is performed by irradiating an inside of the processing chamber with an electromagnetic wave in the first desorption step or the second desorption step.

13. The wafer processing method according to claim 2, wherein
the silicon film is heated to 150° C. or higher in the first desorption step.

14. The wafer processing method according to claim 2, wherein
the first modified layer contains ammonium fluorosilicate.

15. The wafer processing method according to claim 2, wherein
a layer to which the particles of hydrogen, nitrogen, or fluorine adhere is formed on the surface of the silicon film after the first desorption step.

16. The wafer processing method according to claim 2, further comprising:
a purge step of exhausting an inside of the processing chamber to reduce a pressure between the step of forming the first modified layer and the first desorption step or between the step of forming the second modified layer and the second desorption step

17. The wafer processing method according to claim 9, further comprising:
a purge step of exhausting an inside of the processing chamber to reduce a pressure between the step of forming the first modified layer and the step of forming the second modified layer or
between the step of forming the second modified layer and the desorption step.
